(19) United States
(12) Patent Application Publication
(10) Pub. No.: US 2014/0094079 A1
(43) Pub. Date: Apr. 3, 2014

(54) METHOD FOR MANUFACTURING DISPLAY DEVICE

(71) Applicant: KABUSHIKI KAISHA TOSHIBA, Tokyo (JP)

(72) Inventors: Hiroshi ITO, Kanagawa-ken (JP); Mitsuo Sasaki, Kanagawa-ken (JP)

(73) Assignee: Kabushiki Kaisha Toshiba, Tokyo (JP)

(21) Appl. No.: 13/832,859

(22) Filed: Mar. 15, 2013

(30) Foreign Application Priority Data
Sep. 28, 2012 (JP) 2012-216451

(51) Int. Cl. H01J 9/26

(52) U.S. Cl. CPC H01J 9/26
USPC 445/24

(57) ABSTRACT

According to one embodiment, a method for manufacturing a display device is disclosed. The method can include forming a base substrate on a metal layer of a carrier substrate. The method can include forming a display element layer on the base substrate. In addition, the method can include peeling the base substrate from the metal layer by irradiating laser light from a side of the carrier substrate opposite to the metal layer.

### CROSS-REFERENCE TO RELATED APPLICATIONS

This application is based upon and claims the benefit of priority from the prior Japanese Patent Application No. 2012-216451, filed on Sep. 28, 2012; the entire contents of which are incorporated herein by reference.

### FIELD

Embodiments described herein relate generally to a method for manufacturing a display device.

### BACKGROUND

Display devices that include a display element layer formed on a base film made of a polymer material such as plastic, etc., are flexible and can be made in curved surface configurations. In such a display device, to handle the base substrate which is formed of easily-deformable plastic, etc., the base substrate is formed on a carrier substrate; and the base substrate is peeled from the carrier substrate at the final stage of the processes. Accordingly, the technology to perform the peeling using an inexpensive apparatus with little damage to the base substrate is desirable.

### BRIEF DESCRIPTION OF THE DRAWINGS

FIGS. 1A to 1D and FIGS. 2A to 2D are cross-sectional views of processes, illustrating a method for manufacturing a display device according to a first embodiment;

FIGS. 3A and 3B are schematic views describing the peeling of the base substrate, FIG. 3A is a cross-sectional view, and FIG. 3B is an enlarged view of the portion enclosed with broken line A in FIG. 3A;

FIG. 4 is a schematic view showing the state in which the base substrate has peeled;

FIGS. 5A to 5C are cross-sectional views of processes, illustrating a method for manufacturing a display device according to a second embodiment;

FIG. 6 is a plan view illustrating the metal layer of a third embodiment;

FIG. 7 is a cross-sectional view of a process, illustrating the problem when singulating the display devices;

FIG. 8 is a plan view illustrating the metal layer of a fourth embodiment;

FIG. 9 is a cross-sectional view of a process, illustrating a method for manufacturing a display device according to a fifth embodiment; and

FIGS. 10A and 10B are cross-sectional views of processes, illustrating a method for manufacturing a display device according to a sixth embodiment.

### DETAILED DESCRIPTION

According to one embodiment, a method for manufacturing a display device is disclosed. The method can include forming a base substrate on a metal layer of a carrier substrate. The method can include forming a display element layer on the base substrate. In addition, the method can include peeling the base substrate from the metal layer by irradiating laser light from a side of the carrier substrate opposite to the metal layer.

Various embodiments will be described hereinafter in detail with reference to the accompanying drawings. The drawings are schematic or conceptual; and the relationships between the configurations and lengthwise and crosswise dimensions of portions, the proportions of sizes between portions, etc., are not necessarily the same as the actual values thereof. Further, the dimensions and/or the proportions may be illustrated differently between the drawings, even for identical portions. In the drawings and the specification of the application, components similar to those described in regard to a drawing thereinabove are marked with like reference numerals, and a detailed description is omitted as appropriate.

### First Embodiment

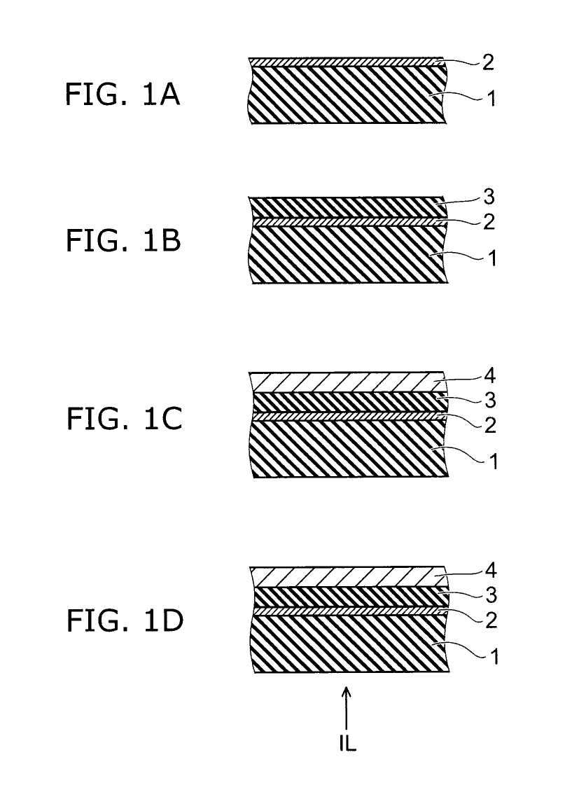

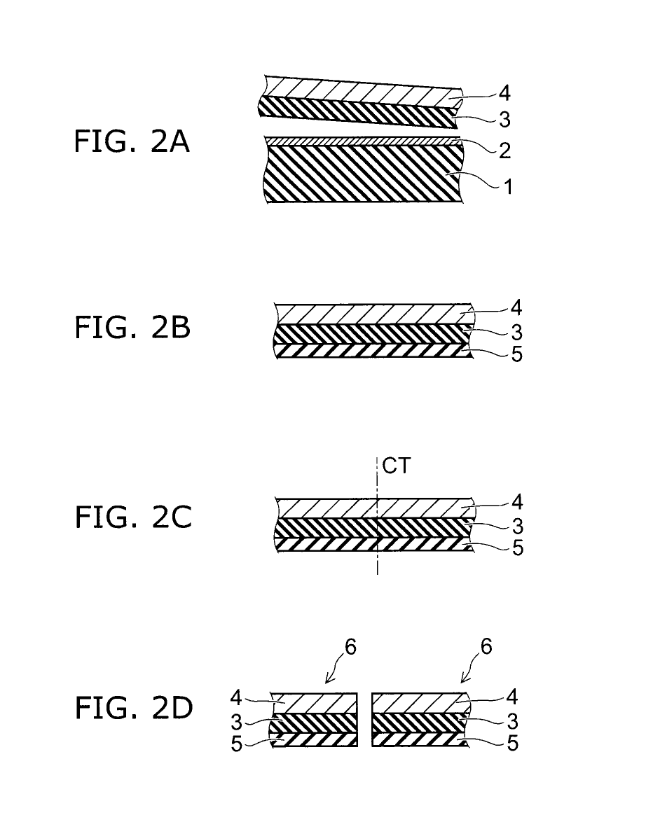

FIGS. 1A to 1D and FIGS. 2A to 2D are cross-sectional views of processes, illustrating a method for manufacturing a display device according to a first embodiment.

The method for manufacturing the display device of the embodiment is a method for manufacturing a display device, e.g., a sheet device, that includes a display element layer formed on a base substrate.

As shown in FIG. 1A, a carrier substrate 1 is prepared on which a metal layer 2 is provided.

The carrier substrate 1 is, for example, glass and functions as a temporary support substrate to form the display device. It is sufficient for the carrier substrate 1 to have moderate strength and to be transmissive to the wavelength of the laser light used in subsequent processes; and the thickness of the carrier substrate 1 is not particularly limited.

The metal layer 2 is formed of, for example, a metal including at least one selected from titanium (Ti), tungsten (W), molybdenum (Mo), nickel (Ni), iron (Fe), and tantalum (Ta) with a thickness of, for example, 50 nm to 200 nm. It is sufficient for the metal layer 2 to be formed of a material that has a high absorptance at the wavelength of the laser light used in subsequent processes, has a relatively high melting point, and has a high thermal capacity. It is sufficient for the absorption amount of the laser light of the metal layer 2 to be greater than the absorption amount of the laser light of the carrier substrate 1. It is sufficient for the metal layer 2 to be made of a material with a film thickness such that the laser light does not pass through to the opposite side to destroy the display element that is formed in subsequent processes; and the metal layer 2 is not limited to the metals that are illustrated.

Then, as shown in FIG. 1B, a base substrate 3 is formed on the metal layer 2. The base substrate 3 is formed of, for example, a polymer material such as plastic, etc., and functions as the substrate of the display device. For example, the base substrate 3 formed to have a thickness of 10 μm to 70 μm, is flexible, and can be made into a curved surface configuration. Because the base substrate 3 deforms easily, the base substrate 3 is formed on the metal layer 2 that is provided on the carrier substrate 1.

The base substrate 3 is formed such that the adhesion strength (the bonding force) between the metal layer 2 and the base substrate 3 is less than the adhesion strength between the carrier substrate 1 and the metal layer 2. Simultaneously, the base substrate 3 is formed such that the adhesion strength between the metal layer 2 and the base substrate 3 is greater than the thermal stress generated at the interface between the carrier substrate 1 and the metal layer 2 and the interface between the metal layer 2 and the base substrate 3 in the temperature range of subsequent processes that form a display element layer 4.

Then, as shown in FIG. 1C, the display element layer 4 is formed on the base substrate 3. The display element layer 4 is a layer that includes, for example, a light emitting element that includes an organic EL (Organic Light Emitting Diode (OLED)) and a drive element. It is sufficient for the display element layer 4 to be able to be formed thinly; and the display element layer 4 may be, for example, a liquid crystal display (LCD) that includes liquid crystal molecules and a polarizer as an optical layer. Although the display element layer 4 is formed by general processes, for example, in the case where the display element layer 4 includes an organic EL element, wet etching cannot be used because the organic EL element is vulnerable to moisture; and the organic EL element is formed by dry etching.

Continuing as shown in FIG. 1D, the base substrate 3 is peeled from the metal layer 2 by irradiating laser light IL from the side of the carrier substrate 1 opposite to the metal layer 2.

The wavelength of the laser light IL is a wavelength such that the carrier substrate 1 has a high transmittance to the laser light IL and is a wavelength such that the laser light IL is absorbed more in the metal layer 2 than in the carrier substrate 1. In other words, the wavelength of the laser light IL is a wavelength such that the absorption amount of the laser light IL in the metal layer 2 is greater than the absorption amount of the laser light IL in the carrier substrate 1. The wavelength of the laser light IL is, for example, 350 nm to 1064 nm, and favorably is a wavelength that can be generated by a near-infrared laser of 800 nm to 1 μm or a semiconductor laser in a region near 700 nm to 900 nm.

The laser light IL is irradiated for a short period of time onto the region of the metal layer 2 where the peeling is to occur. The laser light IL is, for example, pulse laser light from a Q-switched laser, etc. For example, the laser light IL may irradiate continuous light from a fiber laser, a semiconductor laser, etc., in a pulse form; or the laser light IL may appear to be irradiated for a short period of time by being scanned over the metal layer 2.

In the case where the laser light IL is irradiated for a long period of time, not only the metal layer 2 and the base substrate 3 but also the display element layer 4 is heated; and there is a possibility that the display performance may be affected negatively. Therefore, in the embodiment, the laser light IL is irradiated for a short period of time onto the region where the base substrate 3 is to be peeled.

Although the beam configuration of the laser light IL is, for example, a circular spot, the beam configuration is not particularly limited; and the uniformity of the processing can be increased by the beam configuration being, for example, a line configuration or a rectangular configuration.

The laser light IL that passes through the carrier substrate 1 is absorbed by the metal layer 2; and the metal included in the metal layer 2 is heated. At this time, peeling occurs at the interface between the metal layer 2 and the base substrate 3 due to a mechanism such as shock-like thermal stress or an impact elastic wave occurring due to the abrupt thermal expansion of the metal layer 2 or simply the decrease of the adhesion strength of the interface between the metal layer 2 and the base substrate 3 due to the temperature increase.

The inventors discovered that, although cracks occur in the metal layer 2 or the metal layer 2 melts or coalesces in the case where the peak power or energy density of the laser light IL is too high, the base substrate 3 can be peeled from the metal layer 2 without damaging the metal layer 2 by using the appropriate conditions.

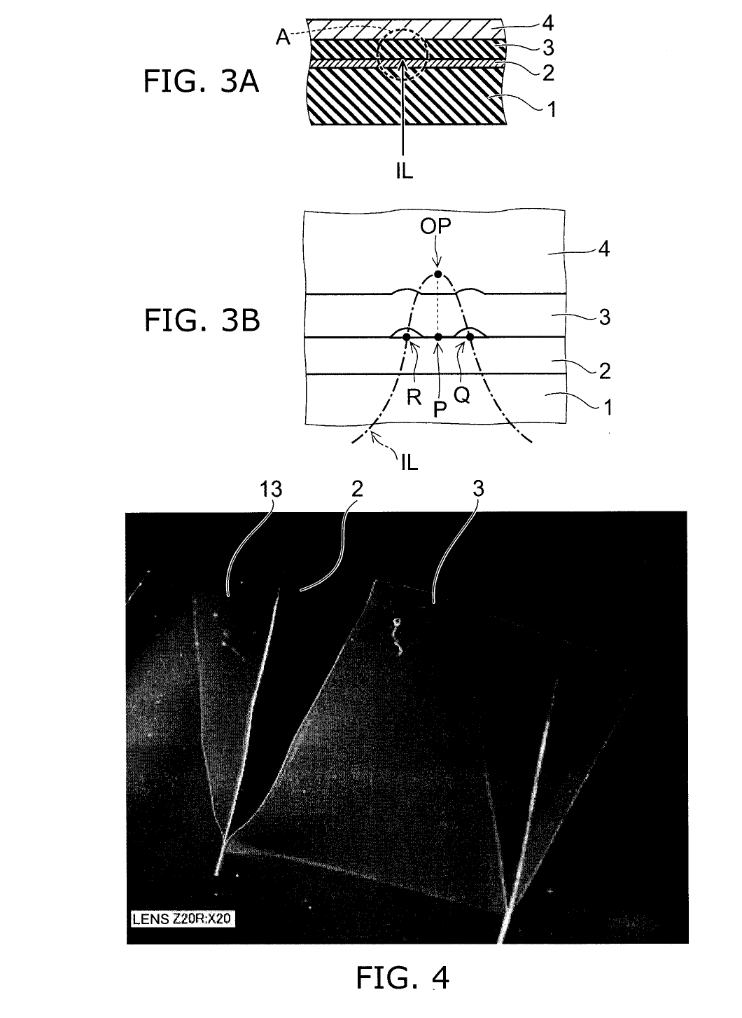

FIGS. 3A and 3B are schematic views describing the peeling of the base substrate. FIG. 3A is a cross-sectional view; and FIG. 3B is an enlarged view of the portion enclosed with broken line A in FIG. 3A.

In FIG. 3B, the intensity distribution of the laser light IL is schematically illustrated by the single dot-dash line; the central portion at the interface between the metal layer 2 and the base substrate 3 where a maximum energy density OP is irradiated is illustrated by P; and boundary portions where the energy density of the laser light IL changes abruptly are illustrated by Q and R.

When the laser light IL is irradiated from the side of the carrier substrate 1 opposite to the metal layer 2 in the region where the base substrate 3 is to be peeled, a temperature gradient occurs between the metal layer 2 and the base substrate 3. For example, as shown in FIG. 3B, the temperature gradient between the metal layer 2 and the base substrate 3 at the boundary portions Q and R where the energy density of the laser light IL changes abruptly is higher than the temperature gradient proximal to the central portion P of the laser light IL. As a result, the base substrate 3 peels from the metal layer 2 proximally to the boundary portions Q and R.

Accordingly, the base substrate 3 can be caused to peel from the metal layer 2 in any region by scanning the laser light IL in the region where the base substrate 3 is to be peeled.

FIG. 4 is a schematic view showing the state in which the base substrate has peeled.

FIG. 4 is a photograph at 20 times magnification illustrating the case where a polyimide film is used as the base substrate 3. A portion of the base substrate 3 has peeled from the metal layer 2; and the base substrate 3 that has peeled is reflected by the metal layer 2 and appears as an image (virtual image) 13. The base substrate 3 has peeled in a substantially square configuration and is connected to the metal layer 2 at one side. The laser light IL is YAG laser light of a wavelength of 1.06 μm.

Thus, by using the appropriate conditions, the base substrate 3 can be caused to peel from the metal layer 2 without damaging the metal layer 2. Accordingly, the carrier substrate 1 can be re-utilized after the peeling because there is no damage to the metal layer 2 (FIG. 2A).

Then, as shown in FIG. 2B, the back-end processes for the base substrate 3 and the display element layer 4 are performed if necessary. For example, in the case where the display element layer 4 is an LCD, a polarizer 5 is provided on the lower surface of the base substrate 3. For example, an optical compensation plate (not shown) such as a phase difference film, etc., is provided.

Continuing as shown in FIG. 2C, display devices 6 are obtained by singulation by cutting the base substrate 3 and the display element layer 4 along a cutting line (dicing line) CT if necessary (FIG. 2D). In the case where multiple display devices are not formed on the carrier substrate 1, it is unnecessary to singulate along the cutting line CT.

Generally, there is a method for peeling a plastic substrate by causing ablation to occur due to the temperature increase at a sacrificial layer or at the plastic substrate surface by laser heating. However, in such a method, the number of processes increases because the peeling occurs at the interface between the sacrificial layer and the glass and it is necessary to remove residue remaining on the plastic substrate and the display element layer that were peeled by, for example, etching, etc.

On the other hand, if it is possible, for example, to cause peeling at the interface due to thermal stress without using ablation in a structure in which the plastic substrate and the glass substrate are in contact, it is unnecessary to add a process of removing the residue such as that recited above. However, according to experiments of the inventors, it was found that in the case where, for example, polyimide is used as the base substrate, even for a fluence (energy density) less than the threshold at which ablation occurs, a phenomenon that is presumed to be a gas component preferentially desorbing from the polyimide is observed; and removal of the polyimide surface or thermal alteration occurs when peeling.

Further, the use of an excimer laser is assumed for the method for causing the ablation by laser heating or the method for peeling the plastic substrate and the glass substrate by thermal stress without using ablation that are recited above. Therefore, the transmittance of the glass for the laser light is low at about 30%; the energy utilization efficiency is low; and the apparatus cost increases.

Conversely, in the embodiment, the base substrate 3 is formed such that the adhesion strength (the bonding force) between the metal layer 2 and the base substrate 3 is less than the adhesion strength between the carrier substrate 1 and the metal layer 2. As a result, the base substrate can be caused to peel from the metal layer by irradiating the laser light. In such a case, the process of removing residue is unnecessary because residue of the metal layer does not remain on the base substrate side. The display performance of the display device is not affected negatively because damage such as thermal alteration, etc., does not occur on the base substrate side. Also, the carrier substrate can be re-utilized because the metal layer is not damaged.

In the embodiment, the base substrate is formed such that the adhesion strength between the metal layer and the base substrate is greater than the thermal stress generated at the interface between the carrier substrate and the metal layer and the interface between the metal layer and the base substrate in the temperature range of the subsequent processes that form the display element layer. As a result, the display device can be manufactured without the base substrate peeling in the processes.

In the embodiment, because it is sufficient for the laser light to be a heat source that heats the metal layer by passing through the carrier substrate, a laser light source of a wavelength substantially in the range of 350 nm to 1064 nm may be used. For example, a near-infrared laser of about 800 nm to 1 μm which includes 1.064 μm or a semiconductor laser of about 700 nm to 900 nm may be used. As a result, the apparatus cost can be lower than that of an excimer laser.

### Second Embodiment

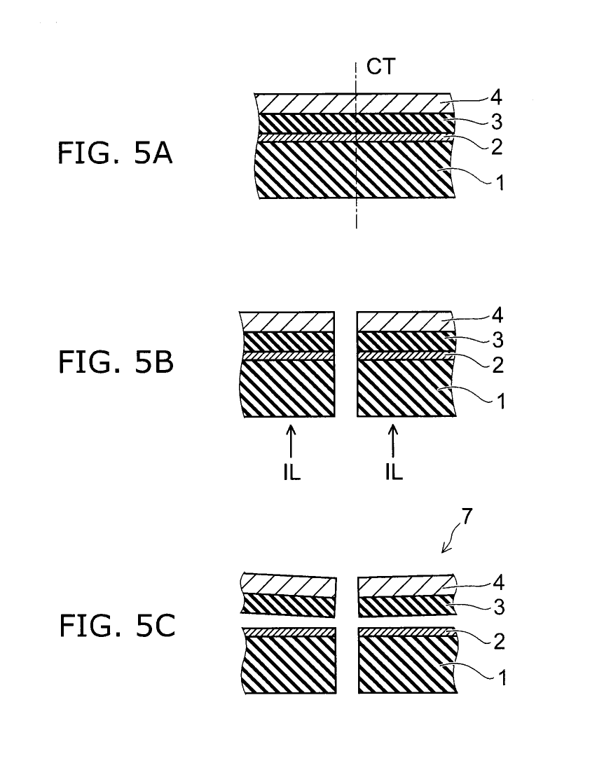

FIGS. 5A to 5C are cross-sectional views of processes, illustrating a method for manufacturing a display device according to a second embodiment.

The method for manufacturing the display device of the embodiment is a method for manufacturing a display device including a display element layer formed on a base substrate and differs from the method for manufacturing the first embodiment in that the display device is singulated.

The processes of the method for manufacturing the embodiment up to the process of forming the display element layer 4 shown in FIG. 1C are similar to those of the first embodiment, and a description is therefore omitted.

The next process will now be described.

As shown in FIG. 5A, singulation is performed by cutting the carrier substrate 1, the metal layer 2, the base substrate 3, and the display element layer 4 along the cutting line CT.

Then, as shown in FIG. 5B, the base substrate 3 is peeled from the metal layer 2 by irradiating the laser light IL from the side of the singulated carrier substrate 1 opposite to the metal layer 2. As a result, singulated display devices 7 are obtained.

Continuing, although not-shown, the back-end processes for the base substrate 3 and the display element layer 4 are performed if necessary. For example, in the case where the display element layer 4 is an LCD, the polarizer 5 is provided on the lower surface of the base substrate 3. For example, an optical compensation plate such as a phase difference film, etc., is provided.

Except for the point that the carrier substrate 1 cannot be re-utilized because the carrier substrate 1 is cut, effects similar to those of the first embodiment can be obtained in the embodiment.

However, there is a possibility that new problems such as (1) to (3) recited below may occur due to the metal layer 2 being provided on the carrier substrate 1 in the first embodiment and the second embodiment.

(1) Alignment marks formed inside the display element layer 4 for the photolithography processes (Photo Engraving Processes (PEPS)) performed when forming the display element layer 4 (FIG. 1B) cannot be read by transmissive detection.

(2) The cutting line CT is not visible from the carrier substrate 1 side during the singulation (FIG. 5A).

(3) In the case where the display element layer 4 side of the base substrate 3 is bonded by ultraviolet (UV) curing, the UV light from outside the carrier substrate 1 does not reach the UV-curing material because the metal layer 2 has a light-shielding effect.

Embodiments that solve problems (1) to (3) will now be described.

### Third Embodiment

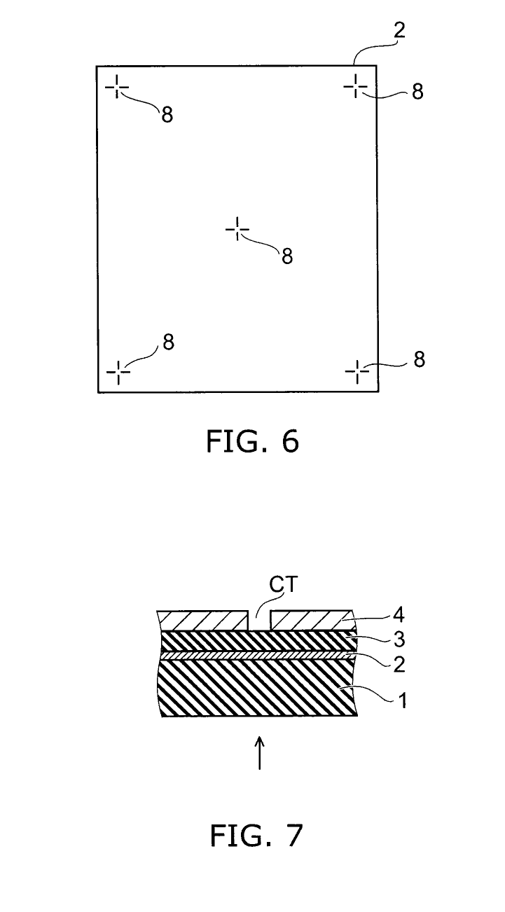

FIG. 6 is a plan view illustrating the metal layer of a third embodiment.

The embodiment solves problem (1) recited above and differs from the first embodiment in that transmissive marks for the alignment are formed at prescribed positions on the metal layer 2 that is provided on the carrier substrate 1. The carrier substrate 1 and the metal layer 2 are similar to those of the first embodiment.

The method for manufacturing the display device of the embodiment includes making transmissive marks 8 defined by removed portions of the metal layer 2 at prescribed positions on the carrier substrate 1 when preparing the carrier substrate 1 (FIG. 1A) on which the metal layer 2 is provided in the method for manufacturing the display device of the first embodiment shown in FIGS. 1A to 1D and FIGS. 2A to 2D. Or, the carrier substrate 1 including the transmissive marks 8 defined by removed portions of the metal layer 2 may be prepared. The transmissive marks 8 may be used as the alignment marks for the alignment in the photolithography processes that form the display element layer 4.

The transmissive marks 8 do not affect the peeling of the base substrate 3 from the metal layer 2 in the case where the transmissive marks 8 are formed, for example, on or proximally to the cutting line CT in a region other than the element formation region where the elements are formed in the display element layer 4. Although the transmissive marks 8 have cross mark configurations in this specific example, the transmissive marks 8 may have any shape or configuration that is usable as the alignment marks for the alignment.

The next process of forming the base substrate 3 on the metal layer 2 and the subsequent processes are performed similarly to those of the first embodiment (FIGS. 1B to 1D and FIGS. 2A to 2D). The configuration in which the display devices are singulated may be the configuration of the second embodiment.

Thus, in addition to the effects of the first and second embodiments, the positional alignment is easier in the embodiment in all of the processes of the photolithography processes performed when forming the display element layer 4 because the transmissive marks 8 defined by removed portions of the metal layer 2 are made on the carrier substrate 1.

FIG. 7 is a cross-sectional view of a process, illustrating the problem when singulating the display devices.

As shown in FIG. 7, problem (2) recited above occurs when the cutting line CT is not visible from the carrier substrate 1 side during the singulation because the metal layer 2 exists. For example, in the case where the singulation is performed prior to the base substrate 3 being peeled from the metal layer 2 as in the second embodiment (FIG. 5C), the cutting line CT is not visible from the carrier substrate 1 side when singulating.

In the case where the singulation is performed after the base substrate 3 is peeled from the metal layer 2 as in the first embodiment (FIG. 2C), the existence of the metal layer 2 is not a problem.

### Fourth Embodiment

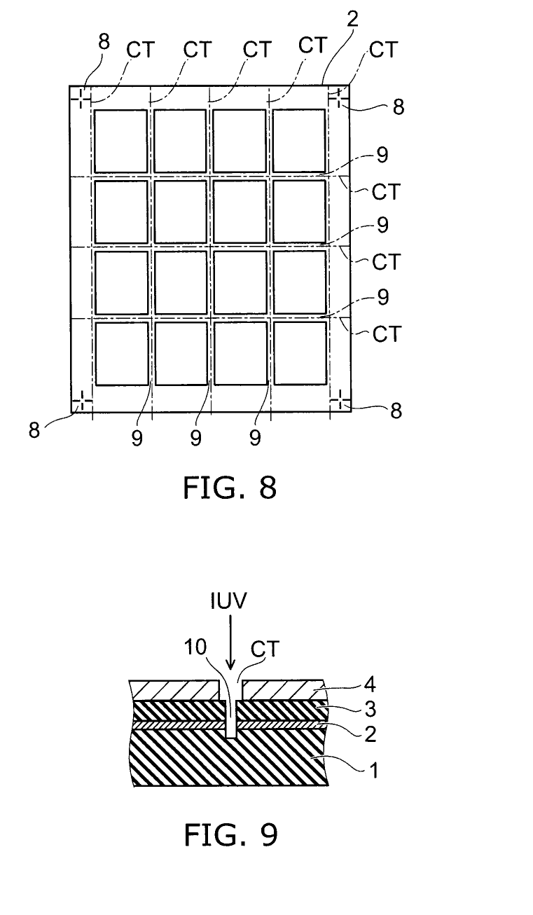

FIG. 8 is a plan view illustrating the metal layer of a fourth embodiment.

The embodiment solves problem (2) recited above and differs from the second embodiment in that a cutting portion 9 is made in the metal layer 2 provided in the carrier substrate 1.

The method for manufacturing the display device of the embodiment includes making the cutting portion 9 defined by a removed portion of the metal layer 2 on the carrier substrate 1 when preparing the carrier substrate 1 (FIG. 1A) on which the metal layer 2 is provided in the method for manufacturing the display device of the first embodiment shown in FIGS. 1A to 1D and FIGS. 2A to 2D. Also, the carrier substrate 1 on which the cutting portion 9 is made may be prepared.

The cutting portion 9 overlaps the cutting line CT when viewed in plan when singulating the display devices in the back-end processes, is made such that the cutting line CT is visible from the carrier substrate 1 side, and is an index for the cutting line CT when singulating.

The next process of forming the base substrate 3 on the metal layer 2 and the subsequent processes are performed similarly to those of the second embodiment (FIGS. 1B to 1C and FIGS. 5A to 5C).

In addition to the effects of the first and second embodiments, the singulation from the carrier substrate 1 side is easier in the embodiment because the cutting portion 9 that is defined by a removed portion of the metal layer 2 is provided on the carrier substrate 1 to be used as an index for the virtual cutting line CT.

### Fifth Embodiment

FIG. 9 is a cross-sectional view of a process, illustrating a method for manufacturing a display device according to a fifth embodiment.

The embodiment solves problem (2) recited above and differs from the second embodiment in that the configuration for the singulation is different.

In the embodiment as shown in FIG. 9, a cutting portion 10 is made by removing a portion of the base substrate 3 and a portion of the metal layer 2 by irradiating laser light IUV from the cutting line CT of the display element layer 4 when singulating. The cutting portion 10 is made to reach the carrier substrate 1 by completely cutting the base substrate 3 and the metal layer 2 at the cutting line CT and is used as an index for the cutting line CT when singulating. The laser light IUV is, for example, ultraviolet pulse laser light.

Then, singulation is performed along the cutting portion 10. The subsequent processes are performed similarly to those of the second embodiment (FIGS. 5B and 5C).

In the embodiment as well, in addition to the effects of the first and second embodiments, the singulation from the carrier substrate 1 side is easier because the cutting portion 10 that is defined by a removed portion of the base substrate 3 and a removed portion of the metal layer 2 is provided as a virtual index for the cutting line CT.

### Sixth Embodiment

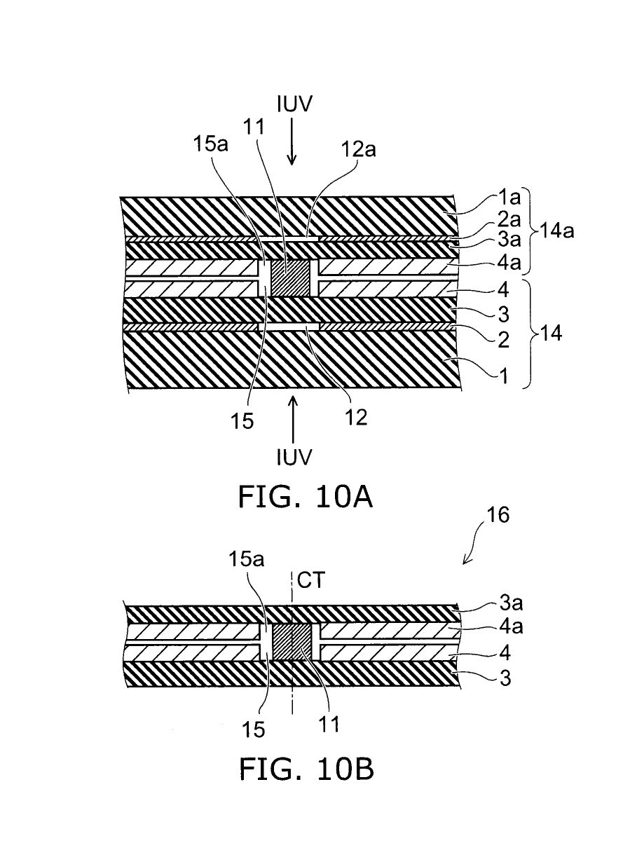

FIGS. 10A and 10B are cross-sectional views of processes, illustrating a method for manufacturing a display device according to a sixth embodiment.

Problem (3) recited above occurs in the case where, for example, when manufacturing an LCD, etc., an array substrate (a first stacked body) in which drive elements are formed at the pixels on a base substrate is bonded to a color filter substrate (a second stacked body) on which color filters are formed at the pixels on a base substrate.

The embodiment solves problem (3) and differs from the first embodiment in that a transmissive portion 12 defined by a removed portion of the metal layer 2 is provided on the carrier substrate 1, and the bonding of the base substrates 3 is performed prior to peeling the base substrate 3 from the metal layer 2 by irradiating the laser light IL from the carrier substrate 1 side (FIG. 1D).

A first stacked body 14 in which the carrier substrate 1, the metal layer 2, the base substrate 3, and the display element layer 4 are stacked is obtained by the process of forming the display element layer 4 on the carrier substrate 1, the metal layer 2, and the base substrate 3 of the first embodiment. The display element layer 4 includes, for example, drive elements formed at the pixels.

In a similar process, a second stacked body 14a in which a carrier substrate 1a, a metal layer 2a, a base substrate 3a, and a color filter 4a are stacked is obtained by forming the color filter 4a instead of the display element layer 4. The color filter 4a includes each of the colored layers of red (R), green (G), and blue (B) corresponding to the subpixels of the pixels.

As recited above, the transmissive portion 12 defined by the removed portion of the metal layer 2 is provided on the carrier substrate 1; and a transmissive portion 12a defined by the removed portion of the metal layer 2a is provided on the carrier substrate 1a. The transmissive portion 12 and the transmissive portion 12a are formed to overlap a connection portion 15, which is a portion on the base substrate 3 where the display element layer 4 is not provided, by a process similar to that of the metal layer 2 of the fourth embodiment. The transmissive portion 12a is formed to overlap a connection portion 15a which is a portion on the base substrate 3a where the color filter 4a is not provided.

Then, as shown in FIG. 10A, the display element layer 4 side of the first stacked body 14 is bonded to the color filter 4a side of the second stacked body 14a by a connection layer 11. The connection layer 11 is, for example, a UV-curing resin that bonds the connection portion 15 to the connection portion 15a.

The bonding of the base substrates 3, i.e., the bonding of the first stacked body 14 and the second stacked body 14a, is performed by curing the connection layer 11 by irradiating, for example, the laser light IUV of ultraviolet from at least one selected from the transmissive portion 12 and the transmissive portion 12a. In the case of a liquid crystal display, for example, a space is made to inject the liquid crystal between the display element layer 4 and the color filter 4a.

Then, although not-shown, in the case where the display element layer 4 is an organic EL, for example, an inert gas, etc., is sealed between the display element layer 4 and the color filter 4a to prevent degradation of the organic EL.

Continuing, the base substrate 3 is peeled from the metal layer 2 by irradiating the laser light IL from the carrier substrate 1 side; and the base substrate 3a is peeled from the metal layer 2a by irradiating the laser light IL from the carrier substrate 1a side.

Then, as shown in FIG. 10B, singulation is performed at the cutting line CT that passes through the connection layer 11.

Thus, in addition to the effects of the first and second embodiments, the first stacked body 14 and the second stacked body 14a can be bonded in the embodiment by, for example, ultraviolet curing of the connection layer 11 which is an ultraviolet-curing resin, etc., because the transmissive portions 12 and 12a defined by removed portions of the metal layers 2 and 2a are provided on the carrier substrates 1 and 1a.

Although an example of a method for manufacturing an LCD is described in this specific example, the embodiment is applicable to the case where the display element layer 4 side of the base substrate 3 is bonded by ultraviolet (UV) curing.

Although not-shown, the polarizer 5 may be provided on the lower surface of the base substrate 3, i.e., the side of the base substrate 3 opposite to the display element layer 4. Also, the singulation may be performed prior to peeling the metal layers 2 and 2a as in the second embodiment. The third to sixth embodiments may be combined appropriately.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a display device, comprising:
forming a base substrate on a metal layer of a carrier substrate;
forming a display element layer on the base substrate; and
peeling the base substrate from the metal layer by irradiating laser light from a side of the carrier substrate opposite to the metal layer.

2. The method according to claim 1, wherein the laser light is absorbed more by the metal layer than by the carrier substrate.

3. The method according to claim 1, wherein an adhesion strength between the metal layer and the carrier substrate is greater than an adhesion strength between the metal layer and the base substrate.

4. The method according to claim 1, wherein the base substrate and the display element layer are singulated after the base substrate is peeled from the metal layer.

5. The method according to claim 1, wherein the carrier substrate is re-utilized after the peeling.

6. The method according to claim 1, wherein the display device including the base substrate and the display element layer is singulated prior to the base substrate being peeled from the metal layer.

7. The method according to claim 6, wherein a cutting portion is provided on the carrier substrate by removing a portion of the metal layer.

8. The method according to claim 6, wherein a cutting portion is made to reach the carrier substrate by removing the base substrate and the metal layer by irradiating laser light from a side of the display element layer prior to singulating the display device.

9. The method according to claim 6, wherein
a transmissive portion is provided on the carrier substrate by removing a portion of the metal layer, and
the base substrate is bonded by curing a connection layer provided on the carrier substrate by laser light irradiated via the transmissive portion from the side of the carrier substrate opposite to the metal layer.

10. The method according to claim 1, wherein a transmissive mark used for alignment is provided on the carrier substrate by removing a portion of the metal layer.

11. A method for manufacturing a display device, comprising:
forming a display element layer on a base substrate of a stacked body including a carrier substrate, a metal layer provided on the carrier substrate, and the base substrate provided on the metal layer; and
separating a stacked body of the carrier substrate and the metal layer from a stacked body of the base substrate and the display element layer by irradiating laser light from a side of the carrier substrate opposite to the metal layer.

12. The method according to claim 11, wherein the laser light is absorbed more by the metal layer than by the carrier substrate.

13. The method according to claim 11, wherein an adhesion strength between the metal layer and the carrier substrate is greater than an adhesion strength between the metal layer and the base substrate.

14. The method according to claim 11, wherein the base substrate and the display element layer are singulated after the separating.

15. The method according to claim 11, wherein the separated stacked body of the carrier substrate and the metal layer is re-utilized.

16. The method according to claim 11, wherein the display device including the base substrate and the display element layer is singulated prior to the separating.

17. The method according to claim 16, wherein a cutting portion is provided on the carrier substrate by removing a portion of the metal layer.

18. The method according to claim 16, wherein a cutting portion is made to reach the carrier substrate by removing a portion of the base substrate and a portion of the metal layer by irradiating laser light from a side of the display element layer prior to singulating the display device.

19. The method according to claim 16, wherein
a transmissive portion is provided on the carrier substrate by removing a portion of the metal layer, and
the base substrate is bonded by curing a connection layer provided on the carrier substrate by laser light irradiated via the transmissive portion from the side of the carrier substrate opposite to the metal layer.

20. The method according to claim 11, wherein a transmissive mark used for alignment is provided on the carrier substrate by removing a portion of the metal layer.
